(19) United States
(12) Patent Application Publication
(10) Pub. No.: US 2026/0045463 A1
(43) Pub. Date: Feb. 12, 2026

(54) Data-Driven Method for Determining Resonant Frequencies in Plasma Process Systems with Multiple Plasma States

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/800,147

(22) Filed: Aug. 12, 2024

(51) Int. Cl. H01J 37/32; H01L 21/67

(52) U.S. Cl. CPC H01J 37/32935; H01J 37/32146; H01J 37/32165; H01J 2237/332; H01L 21/67069

(57) ABSTRACT

Disclosed herein is a system and method for optimizing RF power delivery to a plasma process chamber. This invention utilizes a data-driven approach to determine resonant frequencies for various plasma states, eliminating the need for conventional PID controls. By collecting performance data from an RF power generator as a function of operating frequency during the process recipe execution and analyzing portions of the waveform, the system continuously identifies resonating frequencies for each plasma state. Consequently, the RF power generator adapts in real-time to deliver optimal stability and performance.

### FIELD OF INVENTION

The present invention generally pertains to semiconductor manufacturing. More specifically, it involves a system and method for optimizing radio frequency (RF) power delivery to a plasma process chamber. The invention employs a data-driven approach to identify resonant frequencies for different plasma states without relying on real-time feedback control mechanisms, thereby enhancing the stability and efficiency of semiconductor processing. Additionally, this invention introduces a self-adaptive RF power generator.

### BACKGROUND

In semiconductor manufacturing, precise control of various parameters is essential, particularly in managing RF power delivery to plasma process chambers. Optimizing RF power delivery is critical for ensuring uniformity and high quality in semiconductor devices.

Conventional methods typically use feedback control systems, such as proportional-integral-derivative (PID) controls, to manage RF power delivery. These systems adjust the impedance between the RF power amplifier and the plasma process chamber while accounting for transmission line effects. However, they have limitations. For instance, PID controls can introduce response time delays and are sensitive to noise, potentially degrading the performance of the semiconductor manufacturing process.

These traditional methods depend heavily on real-time control and frequent adjustments, often struggling to stabilize and optimize plasma states, thereby affecting the uniformity and quality of semiconductor production.

Given these challenges, there is a clear need for a method and system that provide better stability and faster control of RF power delivery without relying on real-time feedback mechanisms. A data-driven approach to determining resonant frequencies for each plasma state, avoiding the limitations of conventional PID controls, is essential for improving both stability and performance in semiconductor manufacturing.

### SUMMARY

This invention presents a method and system designed to optimize RF power delivery in plasma process chambers within process systems, thereby enhancing stability and performance.

Conventional RF power generators often utilize feedback controls like PID controls to manage plasma impedance through frequency tuning. However, these methods can suffer from delayed response times and noise susceptibility, negatively impacting performance.

This invention departs from conventional approaches by avoiding the use of PID controls. Instead, it implements a strategy where a system controller reconstructs the process recipe, identifying types of process units associated with distinct plasma states. The controller selects a portion of segments from each type of the process units as setting units, each representing periods of an RF waveform. Varied testing frequencies are assigned to the setting segments, while an initial operating frequency is assigned to all other segments, described as non-setting segments. The frequencies are generated by the system controller with supports from an RF controller.

In some embodiments, the process system includes an RF power generator comprising an RF controller, an RF power amplifier, a resonator, and a voltage-controlled oscillator (VCO) interfaced with the plasma source in the plasma process chamber. Upon receiving a process recipe, the system controller organizes the process units and generates an array of the process units including the segments. Setting segments from each type of the process units are assigned varied testing frequencies, while non-setting segments are assigned the initial operating frequency. The ratio of selected to unselected segments is extremely small, typically below 0.1%, ensuring that the output of the RF power generator is not significantly affected during substrate processing in the plasma chamber.

The RF controller receives the array and generates a pulse train corresponding to the process units and their segments. There may be intervals between process units without ignited plasma. The pulse train is delivered to the VCO, where the amplitude of each pulse determines the operating frequency, which is either a varied testing frequency or the initial operating frequency. As the RF waveform with varied operating frequencies is delivered to the plasma source, a sensor measures performance indicators. Using a predetermined algorithm, the resonant frequency corresponding to each plasma state is determined.

In some implementations, the performance indicators include reflected power from the plasma process chamber. In others, they include phase angle measurement at selected nodes of the resonator or amplifier for specific signals.

This invention uniquely enables the direct generation of resonant frequencies for the RF power generator, bypassing feedback controls and thereby reducing noise susceptibility while enhancing stability and performance. By leveraging extensive data collected during process execution, resonant frequencies for each plasma state can be determined using a statistically sound methodology, eliminating the effects of noise in the RF power generator.

Furthermore, the invention introduces a self-adaptive methodology for the RF power generator. After generating resonant frequencies, the system controller performs a validation procedure according to a predetermined schedule. This validation confirms the resonant frequencies by continuously measuring the performance indicator as a function of the testing frequency centered at the resonant frequency. If the validation procedure is failed, the system controller initiates a new testing procedure to determine new resonant frequencies.

In summary, this methodology ensures that RF power delivery is optimized for process recipes with diverse plasma states, providing a practical solution that significantly enhances the stability and performance of semiconductor manufacturing processes.

### BRIEF DESCRIPTION OF THE DRAWINGS

For enhanced clarity, the following descriptions refer to the accompanying drawings:

FIG. 1: Shows an exemplary process system equipped with a conventional RF power generator.

FIG. 2A: Depicts an embodiment of a self-adaptive RF power generator for a process system.

FIG. 2B: Provides detailed information on generating varied operating frequencies for different process units using a VCO controlled by pulse amplitudes.

FIG. 3A: Illustrates an example of identifying process units using an atomic layer etching (ALE) process.

FIG. 3B: Highlights the periods and segments used in designing a testing procedure for identifying resonant frequencies.

FIG. 4A: Sequentially depicts the steps in an exemplary ALE process, with segments highlighted for use in a testing procedure.

FIG. 4B: Demonstrates the allocation of initial operating frequencies and varied testing frequencies to the selected segments.

FIG. 5A: Outlines a flowchart of a testing procedure for determining resonant frequencies of each plasma state.

FIG. 5B: Displays an example of measured reflected RF power as a function of operating frequencies.

FIG. 6: Presents a flowchart of an exemplarily operation of a self-adaptive RF power generator.

### DETAILED DESCRIPTION

This section provides detailed embodiments of the present invention for comprehensive understanding. While certain specifics are provided for clarity, modifications and variations consistent with the subsequent claims are considered within the scope of the invention. Conventional methods and components are referenced to highlight the distinct features of the invention.

Terms used in this patent disclosure are defined as follows:
Anisotropic ALE or simply ALE: Refers to an etching process in semiconductor manufacturing that removes material layer by layer at the atomic scale, ensuring high control over etch depth.
Process System: Represents the integrated equipment and machinery used in semiconductor manufacturing for various processes like deposition, etching, and cleaning.
Chamber: Represents the enclosed environment within process equipment where semiconductor processes occur, such as etching or deposition.
Vacuum Chamber: Represents an enclosed space with low-pressure conditions, used in semiconductor manufacturing for processes that require controlled atmospheric conditions.
Plasma Process Chamber: A specialized type of vacuum chamber designed for processes involving plasma, used in semiconductor manufacturing for etching and deposition.
Substrate: Refers to the base material, typically a silicon wafer, upon which semiconductor devices are fabricated.
Aspect Ratio: Represents the ratio of the height to the width of a feature on a semiconductor wafer, critical for defining microstructure geometry and performance.
High Aspect Ratio: Refers to features with significantly greater height than width on a semiconductor wafer, posing manufacturing challenges due to the difficulty in achieving uniformity and precision.
RF Power Generator: A device that generates radio frequency power used in semiconductor manufacturing processes to energize plasma for etching or deposition.
Tailored Waveform Generator: A device that produces custom electrical waveforms to optimize plasma processes in semiconductor manufacturing.
Resonator: A device designed to resonate at a specific radio frequency, providing high selectivity and stability at its resonant frequency, crucial for RF impedance matching.
RF Power Amplifier: A device that increases the power of an RF signal, crucial for maintaining desired plasma density and stability during semiconductor processes.
Voltage-controlled Oscillator (VCO): an Electronic Oscillator Whose Frequency Is controlled by an input voltage, used in RF systems to generate precise frequencies for plasma generation.
Frequency Tuning: Adjusting the operating frequency of an RF generator to match the impedance of the load, maximizing power transfer.
Plasma Source: A device that generates plasma used in semiconductor manufacturing for etching, deposition, and surface modification.
Sheath: A boundary layer between plasma and a surface, controlling ion and electron energy and flux, crucial for etching and deposition processes.
Plasma Impedance: The opposition that plasma presents to RF power flow, crucial for efficient power transfer and stable plasma conditions in semiconductor manufacturing.
Plasma State: A specific condition of plasma characterized by a distinct impedance, including both resistive and reactive components.
Process Unit: A distinct segment within a process step, representing a specific plasma state. “Setting units” are segments assigned a testing frequency, while “non-setting units” are not.
Waveform: A graphical representation of a signal over time, showing variations in amplitude, frequency, and phase.
Segment: A specific portion of a waveform with distinct characteristics, such as frequency or amplitude.
Period: The duration of one complete cycle of a waveform, the inverse of its frequency.
Pulsing: Modulating RF power in pulses for better control over energy delivery to the plasma, enhancing process outcomes like etching precision.
Chuck: A component in semiconductor manufacturing equipment that holds the wafer in place during processing.
Electrostatic Chuck (ESC): A chuck that uses electrostatic forces to secure the wafer, providing uniform clamping during semiconductor processes.
Dielectric Window: A non-conductive barrier in a vacuum chamber that allows electromagnetic waves to pass through while maintaining the chamber's atmospheric conditions.
System Controller: The central unit that manages and controls the operations and parameters of a process system, ensuring coordinated functioning.
RF Controller: A device that regulates the RF power supplied to the process chamber, optimizing the semiconductor manufacturing process.
PID Control: A control loop mechanism that regulates process variables like temperature, pressure, and gas flow in semiconductor manufacturing.
Transmission Line: A conductor designed to carry RF signals with minimal loss, used to efficiently transfer RF power from the generator to the plasma source.
Directional Coupler: A passive device that samples a fraction of an RF signal for measurement, helping to monitor and manage RF power.
Bias Unit: A component that generates a controlled voltage to accelerate ions towards the wafer, crucial for processes like etching.
Process Recipe: A detailed set of instructions and parameters for executing a semiconductor manufacturing process, ensuring consistency and precision.

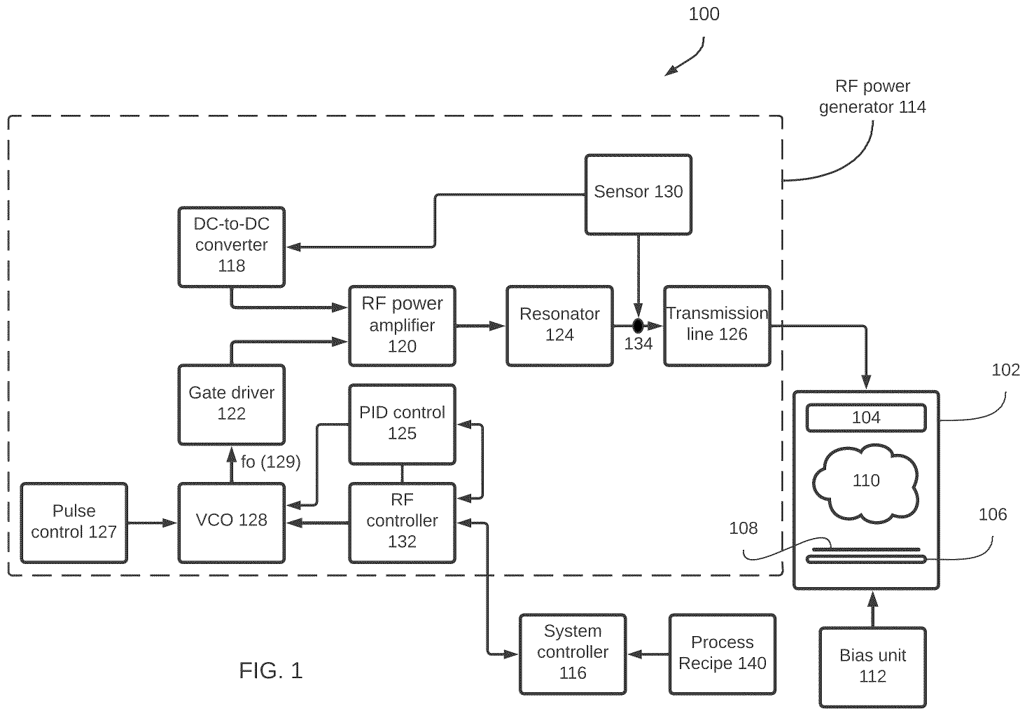

FIG. 1 illustrates a conventional process system (100) incorporating a plasma process chamber (102). Inside or near the chamber (102), a plasma source (104) connects to an RF power generator (114). The chamber (102) provides a vacuum environment conducive to various processing tasks. Although not shown, process gases or precursors enter the chamber through a dedicated delivery unit, and reaction byproducts are removed with a vacuum pump.

Depending on the application, the plasma source (104) can be either an ICP or a TCP, usually positioned adjacent to, yet isolated from, the vacuum chamber through a dielectric window. RF power flows to a coil, generating an electromagnetic field within the chamber (102) and igniting gases to produce a plasma (110), composed of electrons, ions, and neutrals. This plasma facilitates processes like etching a substrate (108) supported by a chuck (106). Plasma etching systems often utilize a bias unit (112) to enhance ion energy through a sheath. The bias unit (112) could be an RF power generator connected to the chuck (106) or might embody a tailored waveform generator. Plasma source (104) and bias unit (112) commonly use pulsing technologies to refine ion energy and angular distribution.

In some cases, a CCP source is employed. Here, both 104 and 106 act as electrodes for the capacitor, accepting RF power from either the top or bottom. This disclosure primarily exemplifies the ICP source paired with the bias unit (112) to explain the inventive concept across various embodiments without limiting the invention's scope.

The RF power generator (114) also incorporates an RF power amplifier (120), which could assume various forms, such as the Class E power amplifier, as recognized in the field. The amplifier's (120) output links to the plasma source (104) through a resonator (124) and a transmission line (126). Often, the resonator (124) is an RF matching circuit containing elements like inductors, capacitors, and resistors, with the capacitors'associated capacitance adjustable either mechanically or electronically. In some implementations, the capacitance of the capacitor is not adjustable, and impedance matching is achieved solely through frequency tuning. The resonator (124) ensures the amplifier's (120) output impedance matches the load impedance presented by the chamber (102) upon plasma (110) ignition. The transmission line (126) might be vital for impedance matching, considering the load impedance created by the chamber (102). The combined impedance of the resonator (124), transmission line (126), and chamber (102) must match the amplifier's (120) output impedance.

A DC-to-DC converter (118) attaches to the amplifier (120), modulating the DC power. A gate driver (122) interfaces with the gates of the amplifier's power MOSFETs, utilizing a resonant circuit to reduce power consumption at the input stage. The operating frequency of the amplifier (120), indicated as fₒ (129), is determined by a signal generator, exemplarily depicted as a VCO (128). The RF power delivered to the plasma source (104) is often pulsed, enabled by a pulse controller (127) coupled to the VCO (128).

State-of-the-art process recipes (140) for the process system (100) might comprise several or many cyclic steps. For instance, a plasma-enhanced anisotropic ALE process includes a surface modification step and a sputtering step in a cycle, repeating multiple or many times to achieve the desired process results. For simplicity, the anisotropic ALE is referred to as ALE throughout this patent disclosure.

During the ALE process's surface modification step, RF power may be cyclically activated and deactivated. Each sub-step with activated plasma can be recognized by a distinct plasma state. Similarly, during the sputtering step, the bias may also be pulsed. In some implementations, bias activation is synchronized with source activation, with this synchronized activation interval representing a distinct plasma state. Therefore, the resonator's (124) resonant frequency might change with each distinct plasma state due to variations in the load impedance related to that plasma state.

Consequently, it's crucial to adjust the operating frequency fₒ (129) when a plasma state changes. Adjusting frequencies involves a PID control (125). The RF controller (132), affiliated with the RF power generator (114), oversees frequency tuning. This controller (132) is also connected to a system controller (116) that directs the overall operations of the process system (100). A sensor (130) aims to determine an RF power generator (114) performance indicator. Using this indicator, the RF controller (132) modulates the VCO (128) output frequency by altering a control voltage for VCO (128) to match the resonator's (124) resonant frequency, incorporating the chamber's (102) real-time load.

In one implementation, the sensor (130) is a directional coupler which is used to measure reflected RF power from the chamber. The directional coupler can be placed in a node as illustrated in FIG. 1 as 134, which is the output of the resonator (124). It can also be placed in other nodes like at the output of the RF power amplifier (120) and at the interface between the RF power generator (114) and the plasma process chamber.

In advanced plasma etching chamber recipes, transitions between process plasma states need to be rapid, nearly instantaneous compared to the processing step durations. Therefore, making mechanical adjustments to the capacitor's capacitance is inefficiently slow. Hence, frequency tuning becomes the primary method for maintaining the resonator (124) in its resonant state. Nonetheless, in certain implementations, variable capacitors can still pre-tune the resonator (124) to allow fine tuning by changing frequency within a range determined by the resonator's bandwidth or quality factor.

Adjusting the frequency to nail down the resonant frequency can be achieved through various techniques. One approach involves measuring the power reflected from the plasma process chamber (102) at the node (134) using the sensor (130). If the reflected power, relative to the input power from the DC-to-DC converter (118), exceeds a predetermined threshold, the RF controller (132) generates a new operating frequency, fₒ (129), by supplying a new control voltage to VCO (128). To hasten the frequency's convergence to the desired resonant frequency, a PID control (125) associated with the RF controller (132) is employed. In alternate setups, the phase difference at chosen nodes is compared to a reference value indicative of the resonator (124) in its resonant condition. The method is also referred as the phase angle method in the art. The PID control (125), integrated with a phase-locked-loop (PLL), ensures the phase difference aligns with this reference value. This PID control (125) can be designed either in a digital or an analog format.

Ordinarily, bringing the resonator (124) to its resonant state through the PID control could take several milliseconds or more. In situations where a rapid pulsing mechanism is operational, this millisecond latency is considered too lengthy. Moreover, increasing the PID control's speed may undermine the RF generator's stability. While an analog PID control affords a shorter settling time than its digital equivalent, it is susceptible to noise like higher-order harmonics. Efforts to eradicate all higher-order harmonics not only complicate the RF circuits but also extend the settling time. A digital implementation of PID control enhances its stability but may be too slow for RF generators where quick response is essential for specific applications like ALE. This invention seeks to resolve these issues.

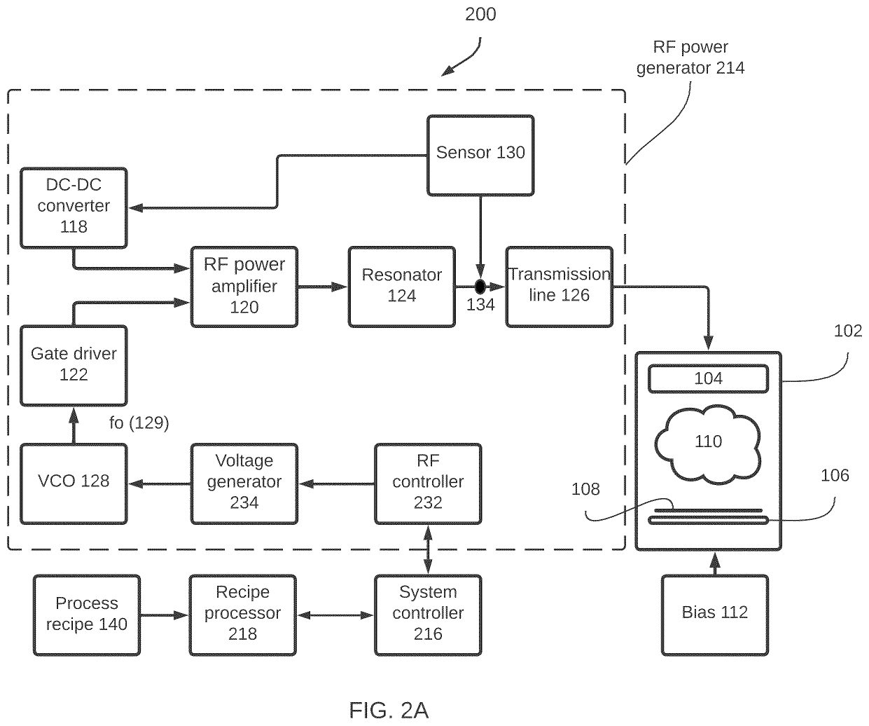

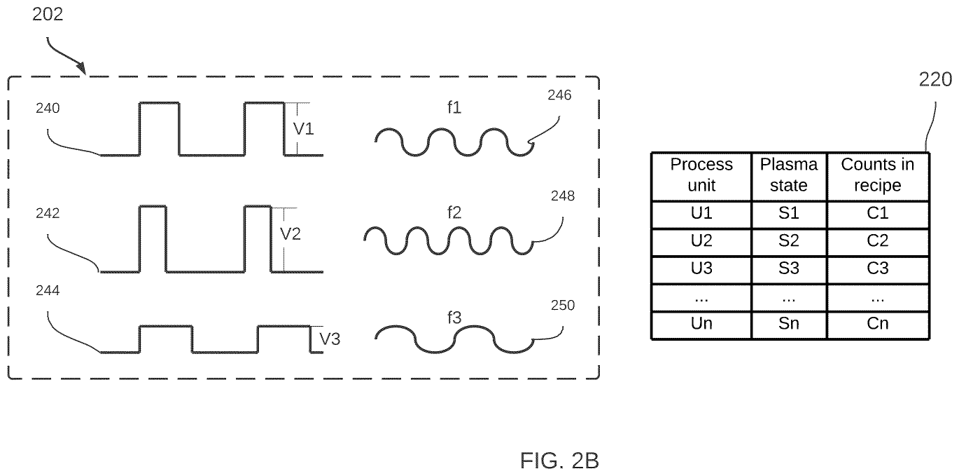

FIG. 2 depicts a functional diagram of a representative embodiment of a self-adaptive RF power generator (214) for a process system (200). This process system (200) incorporates a plasma process chamber (102), which includes a plasma source (104) and a chuck (106) designed to support substrate (108) throughout the process. The chuck (106) is connected to a bias unit (112), which supplies a voltage bias to accelerate ions moving towards the substrate (108). In some implementations, the voltage bias is established by an RF power generator through a block capacitor (not shown in the figure). In other implementations, the voltage bias is provided through a tailored waveform generator to achieve a tight ion energy distribution.

The RF power generator (214) is connected to the chamber (102). The notable difference between RF generators (214) and (114) (from FIG. 1) is the method by which the operating frequency fₒ (129) is generated directly. In the embodiment shown in FIG. 2, the system controller (216) directly provides fₒ (129) to the RF controller (232) in the RF power generator (214). The VCO (128) generates fₒ by adapting to a new control voltage provided by the RF controller (232). The control voltages are delivered in the form of a pulse train, as illustrated in FIG. 2B (202). The pulse train includes, for example, segments like 240, 242, and 244. Each segment belongs to a process unit with a distinct plasma state. The amplitude of each pulse, such as V₁, V₂, and V₃, in the pulse train serves as the control voltage for the VCO (128). The control voltages, delivered as the amplitudes of the pulses, generate the operating frequencies f₁, f₂, and f₃, depicted as 246, 248, and 250, respectively. The RF controller (232) determines the amplitude based on an array sent from the system controller (216), which will be described in detail in the following sections. The PID control (125) is rendered redundant according to this embodiment, allowing the resonator (124) to reach its resonant state within microseconds or less, significantly reducing the time from the previous milliseconds.

The system controller (216) includes a recipe processor (218), which can be implemented as a software program or as a combination of software, firmware, and hardware. The recipe processor (218) analyzes the process recipe (140) and identifies steps and process units in each step. Each process unit is associated with a distinct plasma state with a unique impedance. As shown in Table 220 of FIG. 2B, each process unit Uₓ (where x is an integer from 1 to n) corresponds to a distinct plasma state Sₓ (where x is an integer from 1 to n). At each plasma state, the plasma has a unique impedance Iₓ (where x is an integer from 1 to n) (not shown in the Table). The recipe processor (218) also counts the process units for each plasma state as Cₓ (where x is an integer from 1 to n).

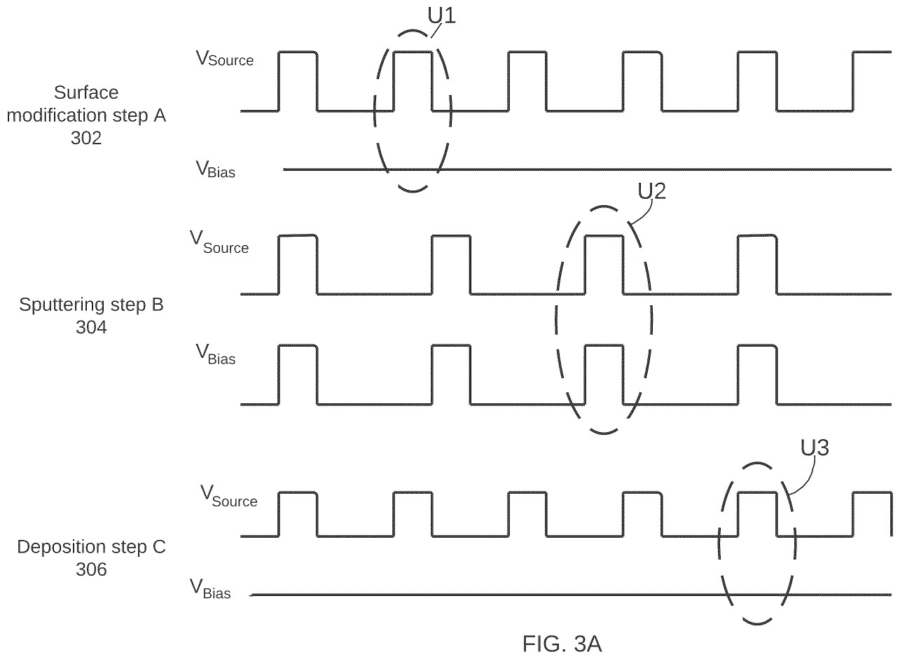

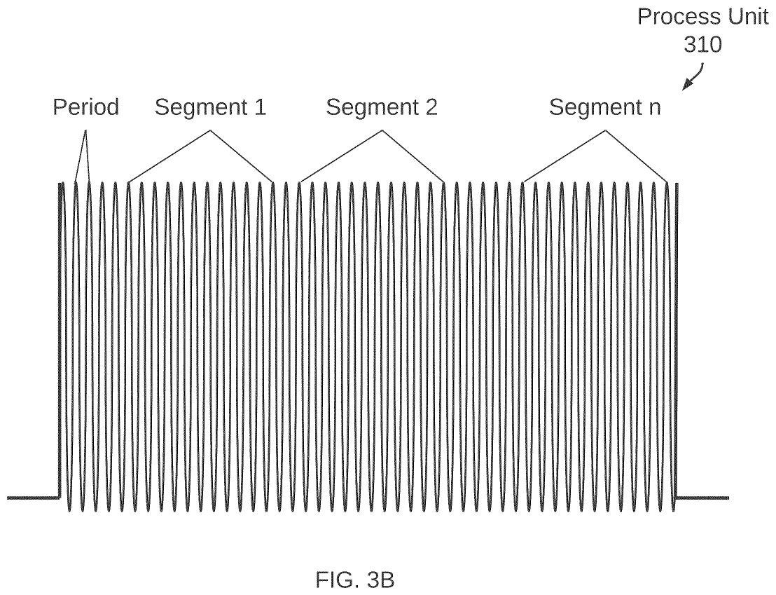

FIG. 3A elucidates a methodological approach to identifying varied process units using an ALE process as an example. The exemplary ALE process includes a surface modification step 302, annotated as “A”. During the surface modification step (302), the RF power generator (214) supplies pulsed RF power to the plasma source (104). The pulsed RF power, denoted as V_{Source}, is applied to the plasma source (104) to reduce spontaneous etching catalyzed by ions during the surface modification step (302). U₁ in FIG. 3A is identified as the first type of the process units characterized by a distinctive plasma state S₁. During the surface modification step, chemically active species are generated to modify the surface of the substrate (108), minimizing spontaneous etching. Throughout the surface modification step (302), the bias unit (112) applies zero bias, indicated as V_{Bias}, to minimize ion energy during this step. The surface modification step (302) reduces the bonding strength of surface atoms and sets the stage for the sputtering step (304) to remove these atoms.

As further illustrated in FIG. 3B, a process unit (310) consists of segments. A segment is defined as a portion of a waveform, and each segment consists of multiple periods. A period is the duration of one complete cycle of the waveform, the inverse of its frequency. For example, if a process unit has a duration of 10 milliseconds, a period with a duration of 100 nanoseconds, and a segment consists of 10 periods, the process unit will have ten thousand segments. In this embodiment, a small portion of these segments are used as setting segments to implement a testing procedure with varied testing frequencies to determine the resonant frequency associated with its plasma state without significantly altering the process outcome. This core inventive concept opens new opportunities to identify the resonant frequency based on real-time data rather than real-time controls. Moreover, the concept can be employed as a method to monitor process or equipment stability without affecting the process outcome during mass production of substrates.

It should be noted that a segment may include a varied number of periods. In some implementations, it may include only one period, while in others, it may include many periods, such as one thousand.

An important note underscores that during the intervals separating various process units, RF power is not applied to either the source (104) or the chuck (106), indicating that these intervals are devoid of any associated process units.

During the sputtering step (304), labeled as “B”, V_{Bias} is applied to the chuck (106) to accelerate ions and remove the modified surface layer. In one implementation, the voltage applied to the plasma source (104), V_{Source}, is pulsed in synchronization with V_{Bias} to achieve a tighter ion energy distribution. U₂, as labeled in FIG. 3A, is identified as the second type of the process units with a distinct plasma state S₂. It should be noted that the resonant frequencies for the plasma source (104) and the bias unit (112) may differ to generate plasma with the state S₂.

A gas used for the sputtering process is often different from the one used in the surface modification step (302). For example, in a silicon ALE process, chlorine is used for the surface modification step (302), while argon is used for the sputtering step (304). Often, the sputtering step operates at a lower chamber pressure than the modification step, making S₂ a different plasma state from S₁. The synchronized pulsing schemes are for illustration only, and there may be many different pulsing schemes known in the art. Therefore, the illustrative scheme should not be considered a limitation of the inventive concept. It should also be noted that the plasma state S₂ may involve two resonant frequencies: one for the plasma source (104) and another for the bias unit (112). The method of utilizing segments can also be applied to the waveform generated by the bias unit (112).

In an exemplary ALE process, as shown in FIG. 3A, a deposition step (306), labeled as process unit “C”, is used to deposit a protective layer along the sidewall of a high aspect ratio structure. The deposition step is not an essential part of the ALE cycles and is used optionally to improve ALE performance. This step (306) may not be included in every ALE cycle comprising steps A and B; it may occur less frequently. The deposition step (306) typically involves different gases or precursors and has a distinct plasma state S₃. The third type of the process units U₃ is labeled in FIG. 3A.

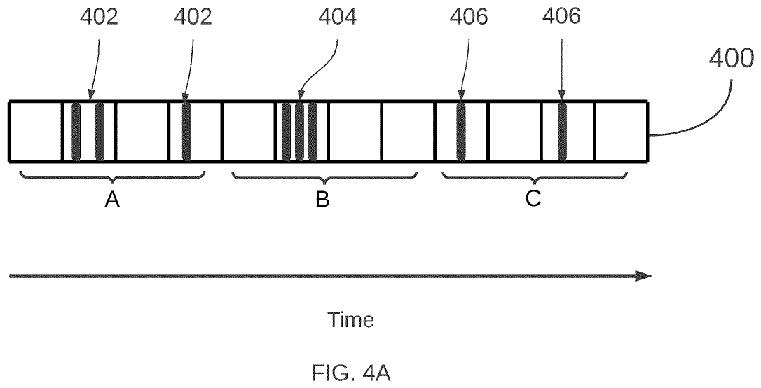

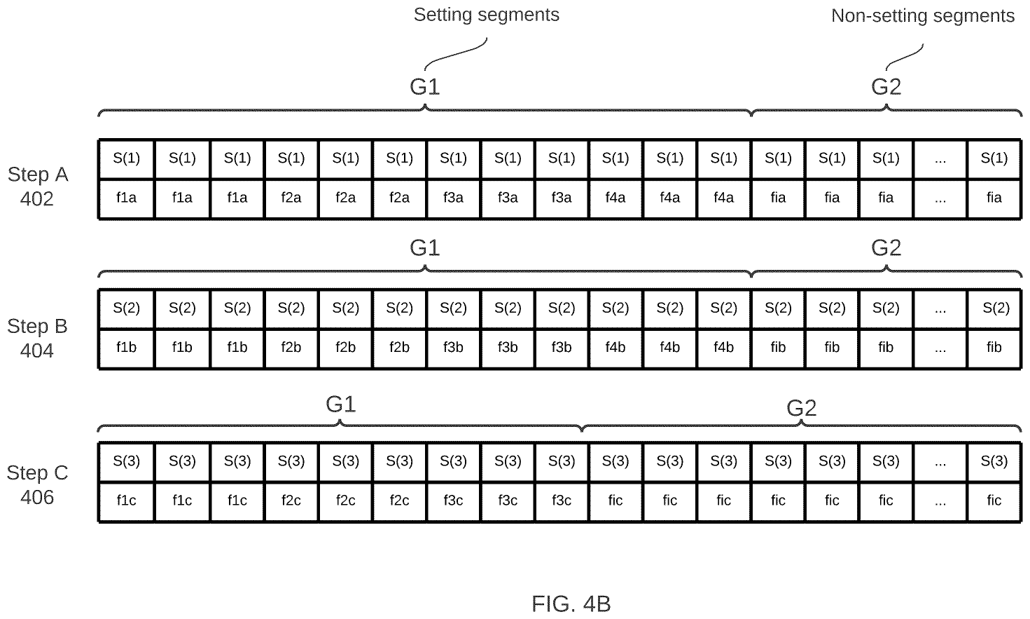

An example of an ALE process 400 in a sequential series of steps A, B, and C is depicted in FIG. 4A. Step A includes multiple segments, denoted exemplarily as 402. The system controller (216) divides the segments (402) into the first group G₁ and the second group G₂. Other than the segments in G₁, all other segments in the waveform are considered as in G₂. Segments (402) in G₁ are setting segments for determining the resonant frequency for the process unit U₁. In a similar manner, segments 404 and 406 are used to determine the resonant frequencies for the process unit U₂ and U₃, respectively. Taking the segments (402) in G₂ as an example, they are assigned by the system controller (216) an initial operating frequency fᵢₐ. The segments (402) in the G₁ are further divided into several sub-groups, each assigned a different testing frequency, labeled exemplarily as f₁ₐ to f₄ₐ as shown in FIG. 4B. In one implementation, the testing frequencies can be generated around the initial frequency fᵢₐ. For example, a testing frequency can be a frequency incrementally increased or decreased from the initial operating frequency in a progressive manner with a range defined by the system controller (216). The range may be within 1-20%, both positively and negatively from the initial frequency fᵢₐ. In a similar manner as illustrated in FIG. 4B, the initial frequencies and the testing frequencies are assigned to G₁ and G₂ of the segments (404) and (406), respectively by the system controller (216). It should be noted that the initial operating frequency for the steps A, B, and C may be different, depending on their respective plasma states.

After each of the process units is assigned an initial operating frequency, the system controller (216) generates an array of the process units in sequence. For the setting segments in the process unit, each segment is assigned an initial operating frequency or varied testing frequency. All un-setting segments are assigned the initial operating frequencies.

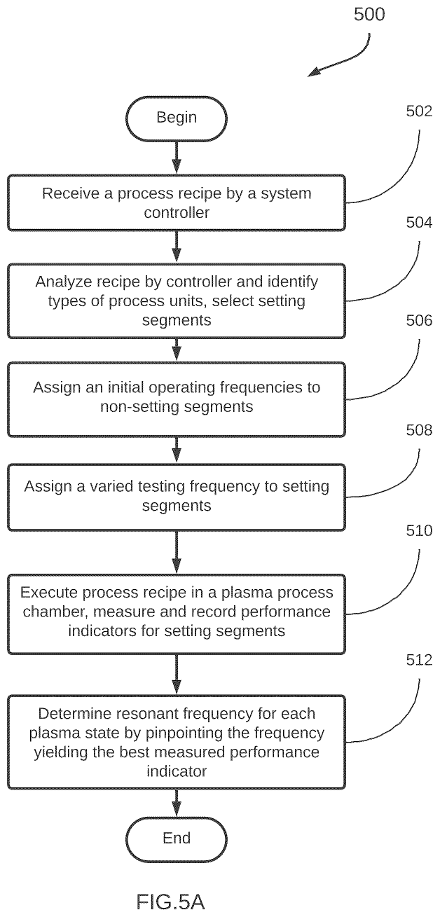

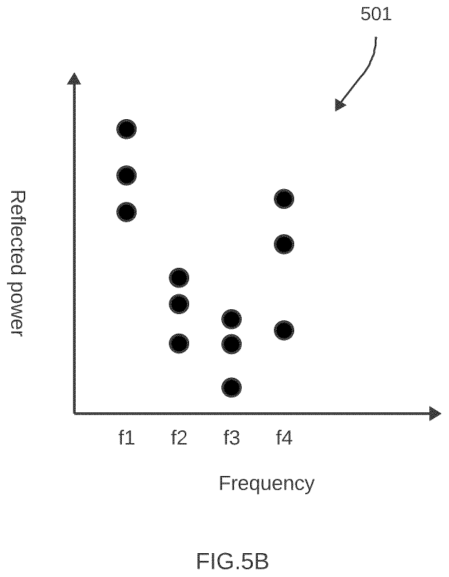

FIG. 5A delineates a flowchart of a testing procedure for determining the resonant frequencies of each type of the plasma states. Process 500 commences with step 502, where a process recipe (140) is received by the system controller (216). The recipe is subsequently analyzed in step 504 by the recipe processor (218), generating Table 220, which identifies process units associated with distinct plasma states. The system controller (216) selects setting segments for each type of the process units. Step 504 may be conducted solely by the system controller in one implementation, while in another, the system controller (216) may execute tasks with user assistance. Alternatively, a user may perform tasks in step 504 and input the Table 220 into the system controller (216) through a user interface.

In step 506, the system controller (216) assigns an initial operating frequency to non-setting segments of each type of the process units. The initial operating frequency for each type maybe different. In step 508, varied testing frequencies are assigned to the setting segments according to a predetermined strategy. In some implementations, the varied testing frequencies are increased or decreased progressively from the initial operating frequency in a range. The range maybe within 1-20% from the initial operating frequency.

In step 510, the process recipe is reconstructed. The reconstructed recipe includes an array of process units, each further comprises setting and non-setting segments. Each segment includes a starting and ending time as well as an assigned operating frequency. The reconstructed process recipe is executed by the system controller (216) for processing of a substrate in a plasma process chamber. The performance indicators are measured by the sensor (130) and recorded in a storage medium of the system controller (216) for each type of the process units.

In step 512, the resonant frequency for each plasma state associated with the process unit can be determined by identifying the testing frequency that yields the best performance indicator. In one implementation, a lookup table listing the measured performance indicators as a function of the testing frequencies can be created. The resonant frequency can be determined by an algorithm which includes but is not limited interpolating and extrapolating the data. In another implementation, a mathematical model may be developed based on collected data. The resonant frequencies can then be determined based on the model. In yet another implementation, the collected data may be employed to train a neural network, and the resonant frequency can then be decided by an inferencing operation of the neural network.

It is imperative to note that the resonant frequency should be determined through a statistically sound method. Given that process system (200) is complex and multiple factors can introduce random variations—including variations in plasma impedance due to parameters such as gas flow, chamber pressure, temperature, and numerous factors linked with RF power generation and delivery—the present inventive concept's distinct advantage lies in its ability to generate and collect a substantial data volume without significantly affecting process outcomes. As showcased exemplarily in 501 in FIG. 5B, performance indicators measured at each of four testing frequencies may demonstrate significant variations. It is therefore imperative to decide resonant frequency in a statistically sound way. A conventional way to find a resonant frequency through a PID control may lead to instability of the system because of noise as elaborated in 501. This issue is overcome through the large volume of the data and statistical methods applied.

Typically, a smaller number of testing segments, ranging from 0.01% to 10% of total segments in the process units, ensure that a slight reduction in RF power delivery related to these units will not substantially, or even detectably, alter the process outcome. The testing segments could be embedded in a production recipe to monitor RF power generator performance in real time, and the system and method are especially suitable if direct frequency generation is employed without any tuning during the process. This enables rapid RF power generation and delivery with the matched impedances without compromising process system stability.

The ample data collected during production enables the filtering out of noise in the RF power generator and system, allowing for the precise determination of the resonant frequency for each of the process units.

In some implementations, the performance indicators are measured while a substrate is being processed in the plasma process chamber. In some other implementations, the testing procedure maybe conducted by a testing run before starting to fabricate the substrate. In still some other implementations, the testing procedure may be scheduled after a number of substrates are processed. All such variations in implementations fall into the scope of the present inventive concept.

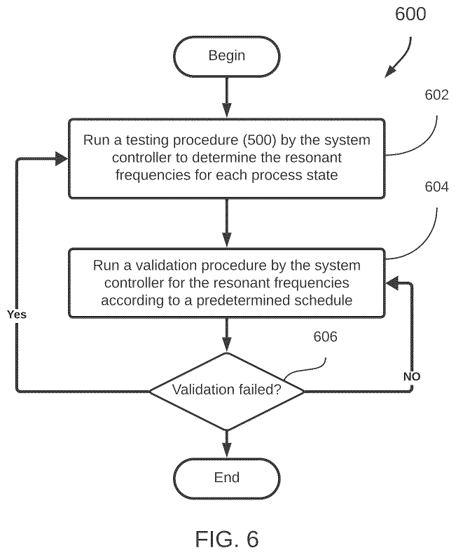

FIG. 6 showcases a flowchart describing an exemplary operation of a self-adaptive RF power generator. Process 600 starts with step 602 that a testing procedure (500) is executed by the system controller (216). The resonant frequencies for each of the plasma states are subsequently determined, where the plasma states are identified by the system controller (216) from a process recipe. After the resonant frequencies are known, a process recipe can be reconstructed and applied to processing of a substrate. During processing of the substrate, a validation procedure can be executed in step 604 by the system controller (216) according to a predetermined schedule.

In one implementation, the validation procedure includes measuring the performance indicators for varied testing frequencies for selected segments in one or more types of the process units.

The varied testing frequencies can be designed to be centered at the resonant frequencies. The performance indicators can be measured as a function of the testing frequency and a relationship is established in real-time. A significant drifting in the relationship indicates failure of the validation procedure in step 606. For example, the validation procedure is failed if the operating frequency corresponding to the best performance indicator is shifted by a predetermined amount. This leads to the system controller (216) to re-run the testing procedure (500) and to learn one or more new resonant frequencies.

In another implementation, the performance indicators are measured continuously at the resonant frequencies. If the measured performance indicator is out of a predetermined range, the validation procedure is failed. For example, the validation procedure is failed if the reflected power is above a predetermined value. The system controller (216) will re-run the testing procedure (500) to determine the new resonant frequencies. A statistical process control (SPC) methodology can be employed herein to track stability for each plasma state either during the execution of a process recipe or over processing of many substrates in production.

The validation procedure will be run continuously in the background. Hence the RF power generator is operated in a self-adaptive manner.

The ALE system is used as an example to elaborate the inventive concept, which can be used to any plasma chambers which include but are not limited to reactive ion etching (RIE) process system, plasma-enhanced chemical vapor deposition (PE-CVD) process system, plasma-enhanced atomic layer deposition (PE-ALD) systems, highly selective etching systems which employ plasma to generate reactive neutrals.

1. A process system, comprising:
a plasma process chamber configured to operate in a vacuum environment;
an RF power generator coupled to a plasma source of the chamber, wherein the RF power generator further comprises an RF power amplifier, a resonator, and a voltage-controlled oscillator (VCO);
a system controller configured to regulate operations of the RF power generator through communication with an RF controller; and
a testing procedure conducted by the system controller to determine a resonant frequency associated with each of the plasma states defined by a process recipe, wherein the testing procedure includes selecting portions of an RF waveform as setting segments, each segment being assigned a varied testing frequency, wherein the resonant frequency is determined based on measured performance indicators by a sensor as a function of the testing frequencies.

2. The system of claim 1, wherein the testing procedure includes a step for producing, by the RF controller, a pulse train with variable amplitudes, said amplitudes serving as control signal directing the VCO to generate designated frequencies stipulated by the system controller.

3. The system of claim 1, wherein the varied testing frequencies allocated to the setting segments bear a defined relationship to an initial operating frequency of the RF power generator, said relationship involving an increment or decrement from the initial operating frequency.

4. The system of claim 1, wherein the sensor is configured to measure reflected power from the plasma process chamber.

5. The system of claim 1, wherein the resonant frequencies are determined using a predetermined algorithm that identifies the resonant frequencies by isolating the frequency associated with the best performance indicator for a plasma state.

6. The system of claim 5, wherein the predetermined algorithm includes the application of statistical methods.

7. The system of claim 1, wherein each segment comprises one or more periods of RF signals.

8. A method for adaptively operating an RF power generator for a plasma process system, the method comprising:
a) running a testing procedure by a system controller to determine a resonant frequency for each of the plasma states, wherein the testing procedure utilizes selected segments of an RF waveform to establish a relationship between a performance indicator and an operating frequency;
b) executing a validation procedure according to a predetermined schedule by the system controller to confirm the resonant frequencies during the processing of one or more substrates in the plasma process chamber, wherein the validation procedure involves verifying the relationship between the performance indicator
and the operating frequency; and
c) repeating steps a) and b) if the validation procedure fails.

9. The method of claim 8, further comprising assigning varied testing frequencies to the selected segments.

10. The method of claim 9, further comprising assigning an initial operating frequency to all unselected segments.

11. The method of claim 8, further comprising generating a pulse train by an RF controller, wherein the pulse train includes at least some pulses with varied amplitudes, and the amplitudes of the pulses are used to generate the initial operating frequency and the varied testing frequencies via a VCO.

12. The method of claim 8, further comprising measuring reflected RF power from the plasma process chamber using a directional coupler.

13. The method of claim 8, further comprising measuring a phase angle of selected signals at selected nodes of the RF power generator.

14. The method of claim 8, further comprising determining the resonant frequencies using statistical methods.

15. The method of claim 8, further comprising updating the process recipe after the resonant frequencies are determined.

16. The method of claim 8, further comprising recording measured performance indicators in a storage medium of the system controller and analyzing the recorded data using a SPC methodology.

17. The method of claim 16, further comprising triggering a re-running of the testing procedure based on the analysis of the recorded data using the SPC methodology.

18. An ALE process system, comprising:
a plasma process chamber configured for an ALE process in a vacuum environment, wherein the ALE process runs in cycles, each cycle including at least a surface modification step and a sputtering step;
an RF power generator coupled to a plasma source of the chamber, wherein the RF power generator further comprises an RF power amplifier, a resonator, and a VCO;
a bias unit coupled to a chuck for supporting a substrate;
a system controller configured to regulate operations of the RF power generator through communication with an RF controller; and
a testing procedure conducted by the system controller to determine resonant frequencies associated with at least a first plasma state in the surface modification step and a second plasma state in the sputtering step,
wherein the testing procedure includes selecting a portion of an RF waveform as setting segments, each setting segment being assigned a varied testing frequency, and wherein the resonant frequency is determined based on measured performance indicators as a function of the testing frequencies, with the performance indicators being measured by a sensor including a directional coupler.

19. The system of claim 18, wherein the testing procedure includes a step for producing, by the RF controller, a pulse train with variable amplitudes for some of the pulses, said amplitudes serving as control signals directing the VCO to generate initial operating frequencies and the varied operating frequencies as instructed by the system controller.

20. The system of claim 18, wherein the system controller further includes a validation procedure for verifying the resonant frequencies during the ALE process and for triggering re-running of the testing procedure if the validation procedure fails.
